(19) United States
(12) Patent Application Publication
(10) Pub. No.: US 2018/0059712 A1
(43) Pub. Date: Mar. 1, 2018

(54) WIRELESS COMMUNICATION APPARATUS, TIME SYNCHRONIZATION METHOD, AND COMMUNICATION SYSTEM

(71) Applicant: FUJITSU LIMITED, Kawasaki-shi (JP)

(72) Inventors: Kenji KAZEHAYA, Yokohama (JP); Mitsurou NAKAJIMA, Yokohama (JP); Shigeaki KAWAMATA, Sagamihara (JP); Yoshinobu IMAI, Machida (JP); Jun ROPPONGI, Yokohama (JP)

(73) Assignee: FUJITSU LIMITED, Kawasaki-shi (JP)

(21) Appl. No.: 15/670,715

(22) Filed: Aug. 7, 2017

(30) Foreign Application Priority Data
Sep. 1, 2016 (JP) 2016-171172

(51) Int. Cl. G06F 1/12; H03K 5/135; G06F 11/07

(52) U.S. Cl. CPC G06F 1/12; H04L 29/0854; G06F 11/0751; H03K 5/135

(57) ABSTRACT

A wireless communication apparatus includes a memory, and a processor coupled to the memory and configured to calculate a variation amount based on a frequency difference between a first clock signal in a first synchronous processing apparatus and a second clock signal in the wireless communication apparatus according to a first message exchanged between the first synchronous processing apparatus and the wireless communication apparatus, calculate a correction amount based on a phase difference between a first time in a second synchronous processing apparatus and a second time in the wireless communication apparatus according to a second message exchanged between the second synchronous processing apparatus and the wireless communication apparatus, and when a failure is detected in the first synchronous processing apparatus based on the variation amount and the correction amount, switch an object for synchronization from the first synchronous processing apparatus to the second synchronous processing apparatus.

### CROSS-REFERENCE TO RELATED APPLICATION

This application is based upon and claims the benefit of priority of the prior Japanese Patent Application No. 2016-171172, filed on Sep. 1, 2016, the entire contents of which are incorporated herein by reference.

### FIELD

The embodiments discussed herein are related to a wireless communication apparatus, a time synchronization method, and a communication system.

### BACKGROUND

In recent years, as measures for rapidly increasing wireless traffic, small-cell formation by the time division duplex (TDD) system has been performed. The TDD system utilizes wireless resources, for instance, in a communication direction (down direction) from a base station apparatus to a terminal apparatus, and in a communication direction (up direction) from the terminal apparatus to the base station apparatus in a time division manner. Thus, in some cases, output timings of a wireless frame at antenna ends are made to match with each other between multiple base station apparatuses, or timings for transmission and reception are made to match with each other between multiple base station apparatuses. In these cases, a reference clock or a reference timing used in each base station apparatus is synchronized with high accuracy between the multiple base station apparatuses.

One of synchronization methods performed between base station apparatuses is known as a time synchronization method based on a Precision Time Protocol (PTP). The PTP is a time synchronization protocol that is standardized as the Institute of Electrical and Electronics Engineers (IEEE) 1588, for instance. In the PTP, a message is exchanged between a PTP-master and a PTP slave, and the time of the PTP slave is synchronized with the time of the PTP-master through the message exchange.

FIG. 21 is a diagram illustrating an example of a time synchronization method using the PTP. A PTP-master regularly transmits an announcement message to a PTP slave. In addition, the PTP-master transmits a Sync message to the PTP slave at a transmission time T1, and the PTP slave receives the Sync message at a reception time T2. The PTP-master transmits information (or time stamp information) at the transmission time T1 using a Sycn follow up message. In contrast, the PTP slave transmits a Delay Request message to the PTP-master at a transmission time T3, and the PTP-master receives the Delay Request message at a reception time T4. The PTP-master transmits information at the reception time T4 to the PTP slave using the Delay Response message.

The PTP slave calculates an average transmission path delay using the times T1 to T4, and calculates a correction amount using the times T1, T2 and the average transmission path delay. The PTP slave is able to obtain a time synchronized with the time of the PTP-master by adding a correction amount to the time of the self-station.

For PTP synchronization, a Boundary Clock (BC) system may be used. FIG. 22 is a diagram illustrating an example of the BC system. One or multiple switching devices (SW1, SW2) are disposed between the PTP-master and the PTP slave. In the example of FIG. 22, PTP synchronization is performed by the PTP-master and the SW1, and the SW1 on the slave side now serves as the master and performs PTP synchronization with the SW2. After that, PTP synchronization is hierarchically performed up to the PTP slave. The BC system allows, for instance, concentration to the PTP-master to be avoided.

However, in the PTP using the BC system, the processing of message exchange at each switch increases as the number of levels in the hierarchical structure increases, and it takes time until time synchronization is performed in the PTP slave at the lowest level. Meanwhile, ±1 μs of a time difference (or an amount of phase difference) between the PTP-master at the highest level and the base station apparatus at the lowest level is allowed in International Telecommunication Union Telecommunication Standardization Sector (ITU-T) standard.

The techniques related to time synchronization include the following, for instance. Specifically, there is a time information transmission apparatus that extracts time information, configuration information, and operation information from a PTP message, stores these pieces of information in a packet transmission apparatus on the downstream, and when an active system is switched to a standby system, passes down these pieces of information from the active system to the standby system.

This technique claims that a sequence after switching the system is omitted, the time in which the downstream packet transmission apparatus is in a self-driven state is minimized, and the most functions of the standby system at the time of normal operation is set to a sleep state, thereby enabling to reduce the power consumption.

Also, there is a communication apparatus that has a clock in an active system and a clock in a standby system, and synchronizes the clock in the active system with an external time source device according to the time information in a packet for synchronization, and synchronizes the time in the standby system with the time in the active system.

This technique claims that degradation of synchronization quality at the time of switching of the clock in the active system may be reduced.

Related techniques are disclosed in, for example, Japanese Laid-open Patent Publication Nos. 2013-243651 and 2014-93540.

### SUMMARY

According to an aspect of the invention, a wireless communication apparatus includes a memory, and a processor coupled to the memory and configured to calculate a variation amount based on a frequency difference between a first clock signal in a first synchronous processing apparatus and a second clock signal in the wireless communication apparatus according to a first message exchanged between the first synchronous processing apparatus and the wireless communication apparatus, calculate a correction amount based on a phase difference between a first time in a second synchronous processing apparatus and a second time in the wireless communication apparatus according to a second message exchanged between the second synchronous processing apparatus and the wireless communication apparatus, and when a failure is detected in the first synchronous processing apparatus based on the variation amount and the correction amount, switch an object for synchronization from the first synchronous processing apparatus to the second synchronous processing apparatus.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an example configuration of a communication system;

FIG. 2A is a table illustrating an example announcement message, and FIGS. 2B and 2C are diagrams each illustrating an example phase margin;

FIG. 3 is a diagram illustrating an example of frequency synchronization;

FIG. 4 is a diagram illustrating an example switching operation of a PTP-master;

FIG. 5 is a diagram illustrating an example change of a variation amount and a correction amount at the time of switching of a PTP-master;

FIG. 6 is a diagram illustrating an example phase margin;

FIG. 7 is a diagram illustrating an example configuration of a BBU apparatus;

FIG. 8 is a diagram illustrating an example configuration of a phase margin detection unit;

FIG. 9 is a diagram illustrating an example configuration of a phase NG detection unit;

FIG. 10A is a table illustrating an example relationship between a frequency deviation and a DDS value, and FIG. 10B is a table illustrating an example phase difference;

FIG. 11A is a graph illustrating an example change in the DDS value, and FIG. 11B is a graph illustrating an example change in the DDS value when a PTP-master fails;

FIG. 12 is a diagram illustrating an example relationship between time and frequency;

FIG. 13 is a diagram illustrating an example relationship between time and frequency;

FIG. 14 is a diagram illustrating an example relationship between time and frequency;

FIG. 15 is a diagram illustrating an example relationship between time and frequency;

FIG. 16A is a diagram illustrating an example phase margin, and FIG. 16B is a diagram illustrating an example access frequency;

FIG. 17 is a flowchart illustrating an example operation;

FIG. 18 is a flowchart illustrating example PTP synchronization establishment processing;

FIG. 19A is a flowchart illustrating example active system PTP-master abnormality coping processing, and FIG. 19B is a flowchart illustrating example standby system PTP-master abnormality coping processing;

FIG. 20 is a diagram illustrating an example configuration of a communication system;

FIG. 21 is a diagram illustrating an example exchange of a message using the PTP protocol; and

FIG. 22 is a diagram illustrating an example BC system.

### DESCRIPTION OF EMBODIMENTS

In the PTP based on the BC system, a failure may occur in a switch between a PTP-master and a PTP slave. Due to a failure of a switch, the PTP slave at the lowest level of a PTP network is set to a self-driven state, and the difference between the time of the PTP slave and the time of the PTP-master may exceed an acceptable range (±1 μs) that is defined in the ITU-T standard. For this reason, the base station apparatus, which is also serving as the PTP slave at the lowest level, may suspend TDD service.

In the above-described technique of passing down the time information, configuration information, and operation information from the active system to the standby system at the time of switching, nothing has been discussed about how to cope with the situation when the difference between the times exceeds an acceptable range due to such a failure of a switch. Consequently, in such a technique, a provided service may be suspended due to a failure of a switch.

Also, in the above-described technique of synchronizing the clock in the active system with an external time source device according to the time information in a packet for synchronization, and synchronizing the time of the standby system, nothing has been discussed about how to cope with the situation when the difference between the times exceeds an acceptable range due to such a failure of a switch. Consequently, also in such a technique, a provided service may be suspended due to a failure of a switch.

Thus, the present disclosure provides a wireless communication apparatus and a time synchronization method that protect against degradation of service.

Hereinafter, an embodiment for implementing the present disclosure will be described. It is to be noted that the embodiments below are not intended to limit the technique in the present disclosure. The embodiments may be combined as appropriate within a range not causing inconsistency between details of processing.

In addition, the terms and technical details described in a specification as a standard related to communication such as the IEEE standard may be used as appropriate in the terms and technical details described in the present specification.

### First Embodiment

<Example Configuration of Communications System>

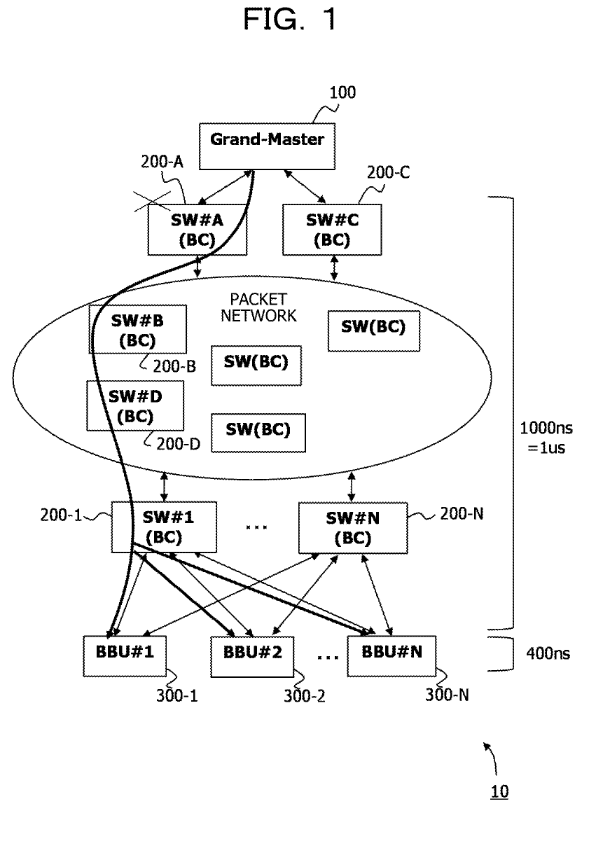

FIG. 1 is a diagram illustrating an example configuration of a communication system 10 in a first embodiment. The communication system 10 includes a grand-master apparatus (hereinafter may be referred to as a “grand-master”) 100, multiple switching devices (hereinafter may be referred to as “switches”) 200-A to 200-D, 200-1 to 200-N (N is an integer 2 or greater), and multiple base band unit (BBU) devices (hereinafter may be referred to as “BBUs”) 300-1 to 300-N.

The grand-master 100 performs, for instance, Global Positioning System (GPS) synchronization, and obtains highly accurate time information compared with the time information in multiple switches 200-A to 200-D, 200-1 to 200-N, and multiple BBUs 300-1 to 300-N. The grand-master 100 performs synchronous processing by the PTP, and performs time synchronization and frequency synchronization with the belonging switches 200-A, 200-C.

Each of the switches 200-A to 200-D, 200-1 to 200-N also performs synchronous processing by the PTP, and performs time synchronization and frequency synchronization with the belonging switches. The switches 200-A to 200-D, 200-1 to 200-N may have a hierarchical structure, for instance. In the example of FIG. 1, the switches 200-A, 200-C are coupled to the grand-master 100, and the switches 200-A, 200-C are coupled to the switches 200-B, 200-D, . . . included in a packet network. The switches 200-1 to 200-N are also coupled to the switches included in the packet network, and are further coupled to the BBUs 300-1 to 300-N.

The grand-master 100, the switches 200-A to 200-D, 200-1 to 200-N, and the BBUs 300-1 to 300-N attempt to establish synchronization with the BC system.

In the example of FIG. 1 illustrates the case where synchronous processing is performed sequentially such as performing synchronous processing between the grand-master 100 and the switch 200-A, performing synchronous processing between the switch 200-A and the switch 200-B, and finally, performing synchronous processing between the switch 200-1 and the BBU 300-1.

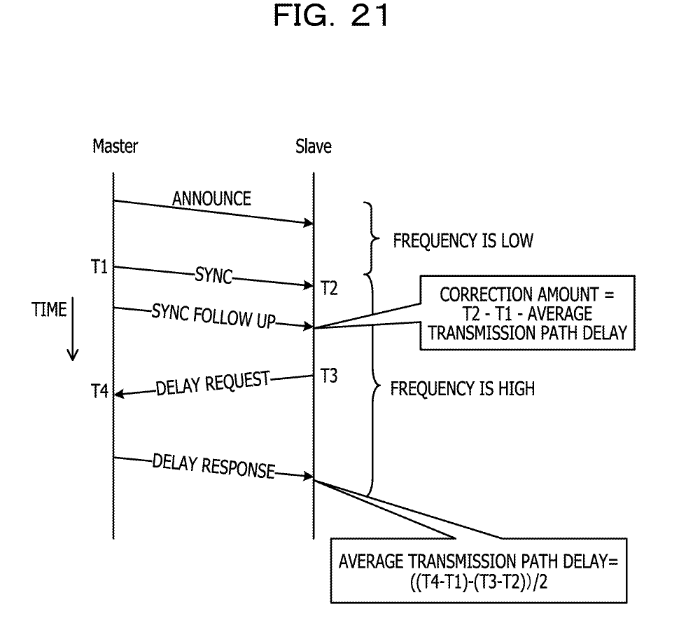

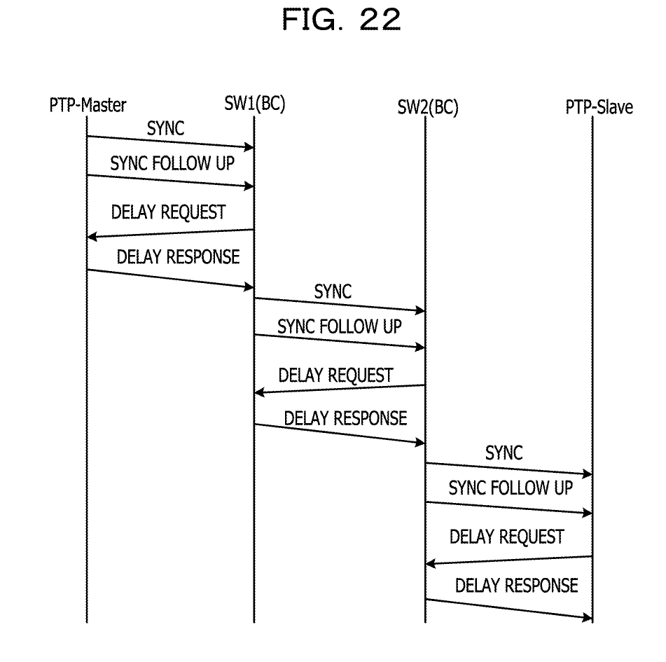

Each of the switches 200-A to 200-D, 200-1 to 200-N may be, for instance, a synchronous processing apparatus that performs synchronous processing. Each of the switches 200-A to 200-D performs synchronous processing by the PTP by exchanging a message defined by the PTP (see, for instance, FIG. 21 and FIG. 22).

The BBUs 300-1 to 300-N are, for instance, base station apparatuses or part of base station apparatuses, and each perform processing related to communication with a terminal apparatus. Each of the BBUs 300-1 to 300-N performs wireless communication, for instance, with a terminal apparatus using the TDD system. Each of the BBUs 300-1 to 300-N is coupled to, for instance, one or multiple remote radio heads (RRH), and forms a so-called remote base station. The RRH performs processing on a radio signal in a radio band, and each of the BBUs 300-1 to 300-N performs processing on data in a baseband. Each of the BBUs 300-1 to 300-N may be coupled to a gateway apparatus to exchange data or the like.

In this manner, the communication system 10 forms a PTP network. The reference timing of the entire communication system 10 is determined by the grand-master 100 that performs GPS synchronization, and is distributed to the switches 200-A to 200-D, 200-1 to 200-N, and the BBUs 300-1 to 300-N.

<Allowable Delay Amount in Communications System>

As described above, in the ITU-T, the difference amount (or acceptable delay amount) in the output timing at the antenna end of a base station apparatus is defined as follows: the difference in a network is 1000 ns and the difference in BBU to RRH is 400 ns, so the total is 1400 ns. Specifically, in the example of FIG. 1, it is determined that the difference (or phase difference) between the time in the grand-master 100 and the time in the BBUs 300-1 to 300-N is ±1000 ns (=±1 μs).

As described with reference to FIG. 21, in the BC system by the PTP, the time taken for synchronous processing by the PTP increases as the number of levels increases. In contrast, in the ITU-T, it is defined that the acceptable difference amount (or acceptable delay amount) per level is ±50 ns in the switches 200-A to 200-D, 200-1 to 200-N. Therefore, in the example of FIG. 1, since the number of levels is four in the path from the grand-master 100 to the BBU 300-1, the difference of ±200 ns (=±50 ns×4 levels) may occur as the worst value of phase difference. In other words, in the BBU 300-1, when the number of levels in the switches 200-A, 200-B, 200-D, 200-1 are identifiable, the worst value of the phase difference of time is identifiable. It is to be noted that the number of levels is also the number of switches 200-A, 200-B, 200-D, 200-1 between the grand-master 100 and the BBU 300-1.

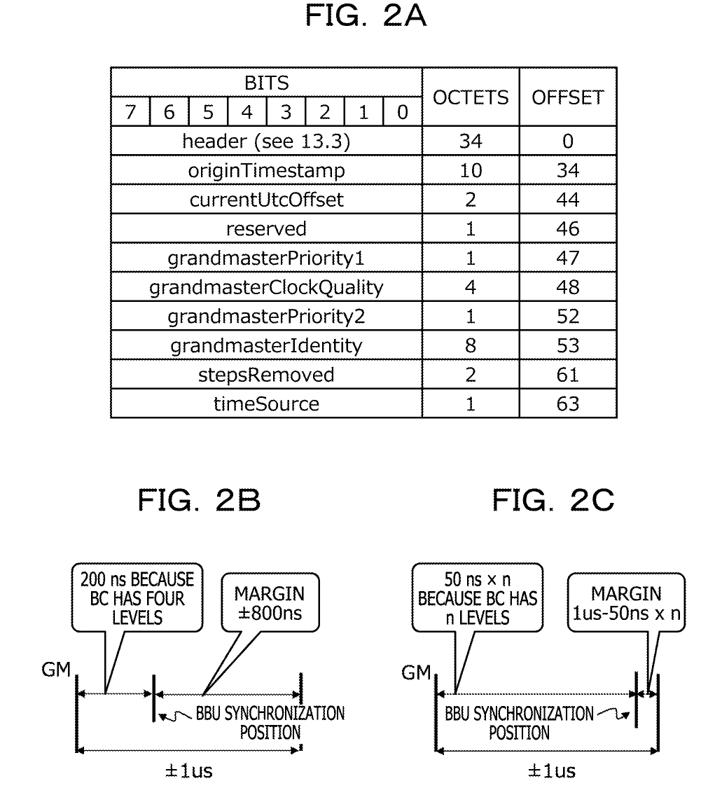

FIG. 2A is a table illustrating an example announcement message. The announcement message has a field of “stepRemoved” that indicates the number of levels. When each of the switches 200-A, 200-B, 200-D, 200-1 receive an announcement message (for instance, FIG. 21), the switch increments the number of levels included in the “stepRemoved” and transmits the announcement message to the switch in the next level. This allows the BBU 300-1 to identify the number of levels.

FIGS. 2B and 2C illustrate an example relationship between the phase difference ±1 μs defined by the standard and the worst value of the phase difference based on the number of levels. In FIG. 2A, when the number of levels is four, the worst value is 200 ns. In this case, a phase margin of ±800 ns is given for the defined phase difference of ±1 In a generalized form, as illustrated in FIG. 2C, when the number of levels is n (n is one or greater), the phase margin is given by 1 μs−50 ns×n.

<Frequency Synchronization by PTP>

In the synchronous processing by the PTP, time synchronization and frequency synchronization are possible. The time synchronization has been described using FIG. 21. Here, the frequency synchronization will be described.

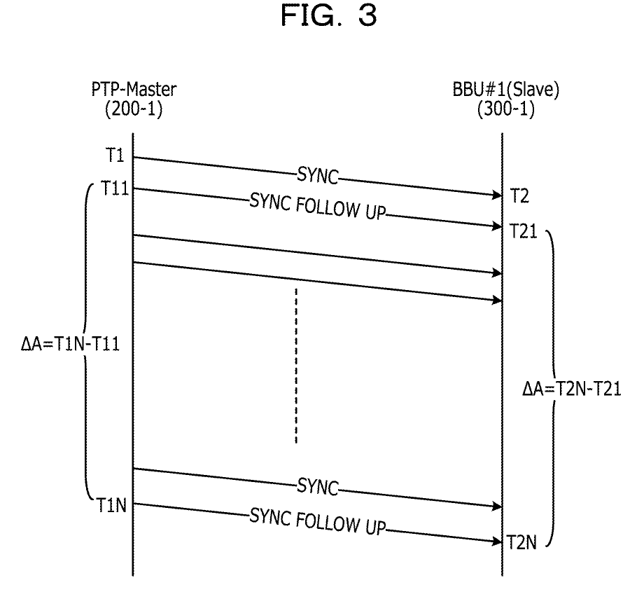

FIG. 3 is a diagram illustrating example frequency synchronization by the PTP. For instance, a PTP-master (which is assumed to be the switch 200-1 here) transmits a Sync follow up message at a predetermined period A based on an oscillating frequency FL In contrast, a PTP slave (which is assumed to be the BBU 300-1 here) receives the Sync follow up message at a predetermined period A based on an oscillating frequency F2. Here, when the oscillating frequency F2 of the PTP slave 300-1 is synchronized with the oscillating frequency F1 of the PTP-master 200-1, the transmission interval ΔA=T1N−T11 and the reception interval ΔB=T2N−T21 for the Sync follow up message are equal. In other words, ΔA=ΔB indicates that the oscillating frequency F1 of the PTP-master 200-1 and the oscillating frequency F2 of the PTP slave 300-1 are synchronized with each other, and ΔA≠ΔB indicates that the oscillating frequency F1 and the oscillating frequency F2 are not synchronized with each other. Thus, the PTP slave 300-1 only has to calculate ΔA and ΔB and adjust the oscillating frequency F2 so that a comparison result is “0”. For instance, the formula for a frequency difference to be calculated by the PTP slave 300-1 is, for instance, as follows.

ΔA−ΔB=(T1N−T11)−(T2N−T21) (1)

<Example Switching Operation at Occurrence of Failure>

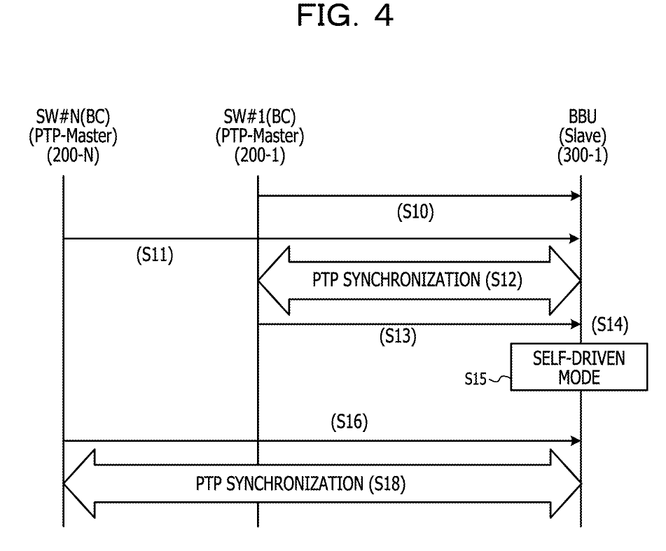

FIG. 4 is a diagram illustrating an example switching operation in the BBU 300-1 when a failure occurs in the switch 200-1 while synchronous processing is performed with the switch 200-1 by the PTP.

Initially, the BBU 300-1 receives an announcement message from each of the switches 200-1, 200-N, and selects the switches 200-1, 200-N each serving as a PTP-master based on the received announcement message (S10, S11). When there are multiple apparatuses serving as a PTP-master, the BBU 300-1 determines a PTP-master using the Best Master Clock (BMC) algorithm. The BMC algorithm is an algorithm defined by the PTP, for instance. The BMC algorithm determines a PTP-master based on intentionally set priority, CLK performance (such as a clock class, a clock accuracy) included in an announcement message. In the example of FIG. 4, the BBU 300-1 determines that the PTP-master is the switch 200-1, using the BMC algorithm.

The BBU 300-1 performs synchronous processing by the PTP with the switch 200-1 which serves as the PTP-master (S12). The switch 200-1 and the BBU 300-1 exchange one announcement message, for instance, every second, and exchange a Sync message to a Delay Response multiple times per second (for instance, 128 times). The exchange frequency of the announcement message is lower than the exchange frequency of other messages.

Subsequently, when a failure occurs in the switch 200-1 serving as the PTP-master, the switch 200-1 notifies the BBU 300-1 that a failure has occurred by an announcement message (S13). At the time of normal operation, “grand-masterClockQuality” (see, for instance, FIG. 2A) included in an announcement message includes, for instance, information indicating the frequency accuracy of the grand-master 100. However, due to a failure of the switch 200-1, the switch 200-1 includes information indicating a more degraded frequency accuracy than the frequency accuracy of the grand-master 100 in the “grand-masterClockQuality” to transmit the information.

The BBU 300-1 serving as a PTP slave detects that the frequency accuracy has been degraded based on the “grand-masterClockQuality”, and once switches to self-driven mode (S14, S15).

The self-driven mode is, for instance, a mode in which a PTP slave does not perform synchronous processing with a PTP-master, and synchronous processing is performed using a signal in the PTP slave. The BBU 300-1, which has made transition to the self-driven mode, is unable to determine whether or not the defined phase difference of ±1 μs is satisfied with respect to the grand-master 100. Thus, the BBU 300-1 stops the TDD service (S14).

Subsequently, the BBU3 00-1 monitors the announcement message and selects a new PTP-master (here, the switch 200-N) utilizing the BMC algorithm. The BBU 300-1 performs synchronous processing with the selected switch 200-N by the PTP, and resumes the TDD service (S17, S18).

In the case of the processing illustrated in FIG. 4, the BBU 300-1 stops the operation of the TDD service. Consequently, the BBU 300-1 causes reduction of service to the belonging terminal apparatuses. Also, after switching to the self-driven mode, the BBU 300-1 receives an announcement message transmitted from another switch, and subsequently, selects a new PTP-master (S16, S17). As described above, the transmission frequency of the announcement message is lower than the transmission frequency of other messages, and for instance, is one second interval. Therefore, after receiving an announcement message from the switch 200-1, the BBU 300-1 stays in standby for at least one second until an announcement message from the switch 200-N is received, and thus it takes time for switching. Consequently, the period of suspended TDD service increases accordingly.

Thus, in the first embodiment, the BBU 300-1 (PTP slave) is coupled to the PTP-master in the active system and the PTP-master in the standby system. The BBU 300-1 performs synchronous processing by the PTP with the PTP-master in the active system. For the PTP-master in the standby system, the BBU 300-1 monitors a correction amount for a time extracted by the synchronous processing using the PTP. In addition, the BBU 300-1 monitors a variation amount in the frequency difference (or frequency deviation) between a clock signal (or a reference signal) of the self-station and a clock signal extracted by synchronous processing using the PTP. The BBU 300-1 detects the presence or absence of a failure of the PTP-master in the active system based on the correction amount and the variation amount. Upon detecting a failure of the PTP-master in the active system, the BBU 300-1 attempts to switch the coupling from the PTP-master in the active system to the PTP-master in the standby system.

Therefore, the BBU 300-1 is able to detect a failure of the PTP-master in the active system without waiting for receiving an announcement message, and thus switching between the PTP-masters may be made quickly. Also, due to quick switching, it is possible for the BBU 300-1 to continue the TDD service without making transition to the self-driven mode. Consequently, the BBU 300-1 is able to protect against degradation of service due to a failure of the PTP-master. The details will be described later.

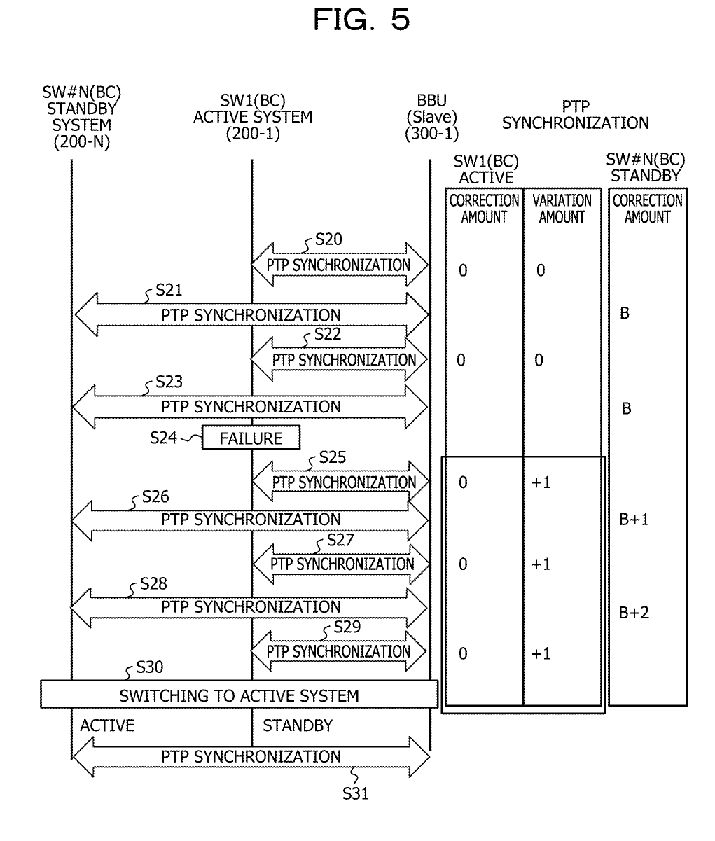

FIG. 5 is a diagram illustrating an example switching operation in the first embodiment. The BBU 300-1 serving as a PTP slave is coupled to the switch 200-1 serving as the PTP-master in the active system and the switch 200-N serving as the PTP-master in the standby system, and performs synchronous processing by the PTP (S20 to S23).

The BBU 300-1 monitors a correction amount of time to the switch 200-N, and further monitors a variation amount in the frequency deviation. When the switches 200-1, 200-N and the BBU 300-1 are in normal operation without a failure, the correction amount and the variation amount do not vary, and maintain a nearly fixed amount.

When a failure occurs in the switch 200-1, the correction amount and the variation amount change, and detection of the change allows a failure of the switch 200-1 to be detected (S25 to S29). Subsequently, when detecting a failure, the BBU 300-1 performs switching processing (S30), and performs synchronous processing by the PTP using the switch 200-N as a PTP-master in the active system (S31).

In FIG. 5, a switching operation has been described briefly. A detailed operation example such as a relationship between the correction amount and the variation amount will be described later.

<Frequency of Access to PTP-Master in Standby System>

In the first embodiment, even in normal time, the BBU 300-1 serving as a PTP slave is coupled to the switch 200-N serving as the PTP-master in the standby system, and performs synchronous processing by the PTP (for instance, S21, S23 in FIG. 5).

However, when the BBU 300-1 performs synchronous processing by the PTP with the switch 200-N serving as the PTP-master in the standby system at the same access frequency as that of the switch 200-1 serving as the PTP-master in the active system, a load to the PTP network may occur.

Thus, in the first embodiment, the BBU 300-1 attempts to reduce the frequency of access to the switch 200-N serving as a PTP slave in the standby system.

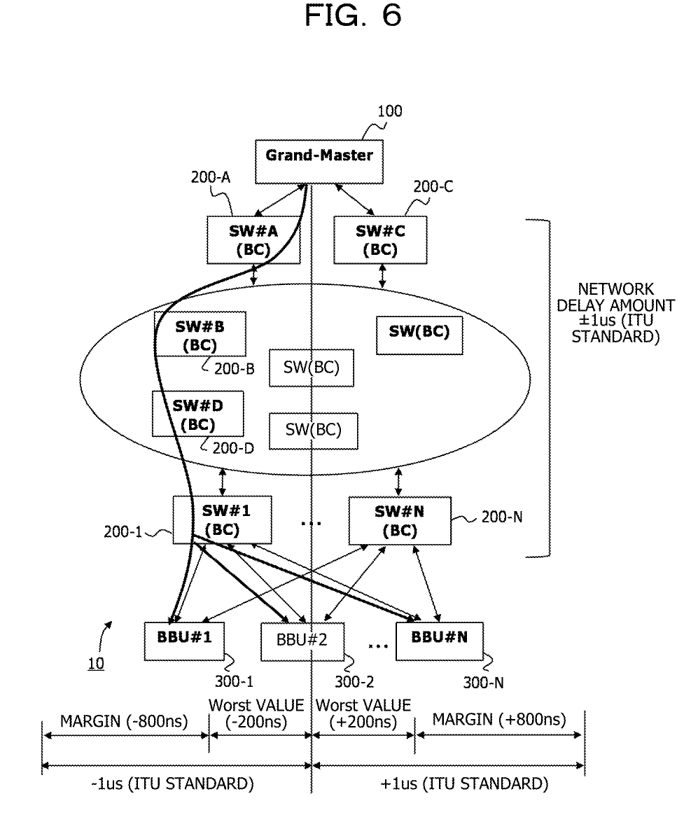

FIG. 6 illustrates example calculation of an access frequency. As described above, an acceptable amount of phase difference in the ITU-T standard is ±1 μs, and it is possible for the BBU 300-1 to calculate a phase margin (±800 ns in the example of FIG. 6) according to the number of levels (four levels) of the switches 200-A, 200-B, 200-D, 200-1. The details will be described later.

In the first embodiment, the BBU 300-1 determines a frequency of access to the PTP-master in the standby system based on the phase margin. For instance, the larger the phase margin is, the longer time is left until a failure is detected. Thus, the number of synchronous operations to a PTP-master in the standby system may be made smaller than in normal time. The details will be described later.

<Example Configuration of BBU>

Next, an example configuration of the BBUs 300-1 to 300-N will be described. The BBUs 300-1 to 300-N may be described as the BBU 300 unless otherwise stated. Also, the switches 200-A to 200-D, 200-1 to 200-N may be described as the switch 200 unless otherwise stated.

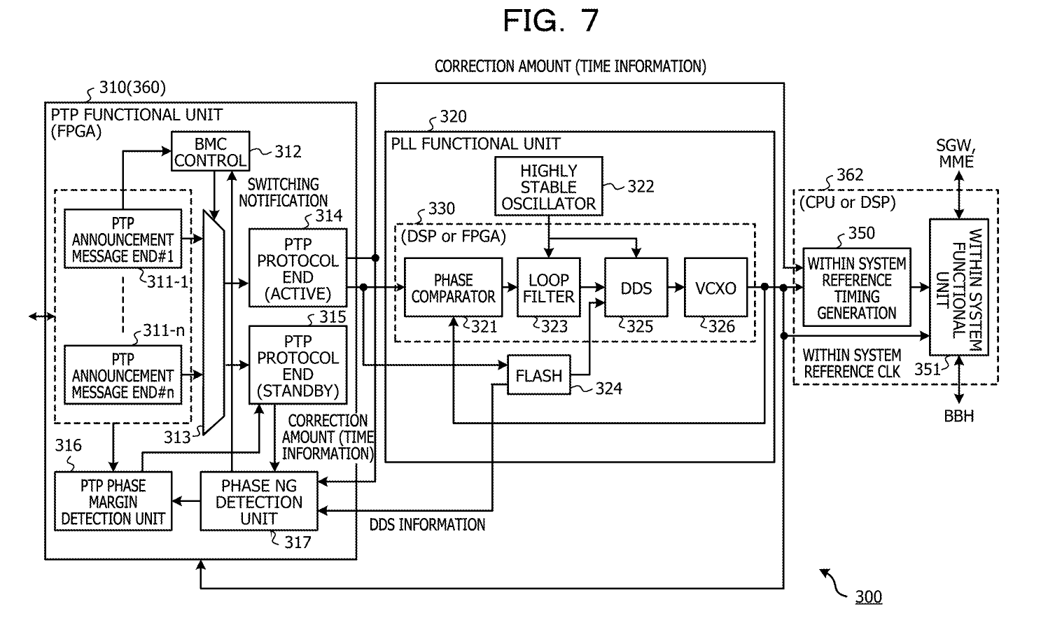

FIG. 7 is a diagram illustrating an example configuration of the BBU 300. The BBU 300 includes a PTP functional unit 310, a PLL functional unit 320, a within system reference timing generation unit 350, and a within system functional unit 351.

The PTP functional unit 310 receives an announcement message transmitted from the switch 200, and selects a switch 200 which serves as a PTP-master, based on the received announcement message. The PTP functional unit 310 performs synchronous processing by the PTP with the selected switch 200, calculates an amount of correction to the time (time information), and outputs the calculated correction amount to the within system reference timing generation unit 350. In addition, the PTP functional unit 310 generates a clock signal extracted by the synchronous processing by the PTP, and outputs the clock signal to the PLL functional unit 320. The frequency of the clock signal matches the frequency (or oscillating frequency) of a clock signal used by the switch 200 serving as a PTP-master, for instance.

The PTP functional unit 310 includes PTP announcement message end sections (hereinafter may be referred to as “message end sections”) 311-1 to 311-n, a BMC control unit 312, a switching unit 313, and a PTP protocol end section (in active) (hereinafter may be referred to as an “active system protocol end section”) 314. The PTP functional unit 310 further includes a PTP protocol end section (in standby) (hereinafter may be referred to as a “standby system protocol end section”) 315, a PTP phase margin detection unit (hereinafter may be referred to as a “phase margin detection unit”) 316, and a phase NG detection unit (hereinafter may be referred to as a “phase detection unit”) 317.

Each of the message end sections 311-1 to 311-n receives an announcement message transmitted from each switch 200, and extracts announcement information such as clock quality included in the received announcement message. Each of the message end sections 311-1 to 311-n output the extracted announcement information to the BMC control unit 312, the switching unit 313, and the phase margin detection unit 316. Each of the message end sections 311-1 to 311-n receives messages (such as a Sync message) using the PTP other than the announcement message transmitted from the switch 200, and outputs the received message to the switching unit 313.

The BMC control unit 312 performs the BMC algorithm based on the announcement information received from the message end sections 311-1 to 311-n, and selects a switch 200 which serves as a PTP-master. The BMC control unit 312 outputs a switching control signal to the switching unit 313, the switching control signal causing the selected switch 200 to be a PTP-master in the active system. In this case, the BMC control unit 312 also selects a switch 200 which serves as a PTP-master in the standby system, utilizing the BMC algorithm, and outputs a switching control signal to the switching unit 313, the switching control signal causing the selected switch to be a PTP-master in the standby system.

Also, upon receiving a switching notification from the phase detection unit 317, the BMC control unit 312 outputs a switching control signal to the switching unit 313 in accordance with the switching notification, the switching control signal causing the PTP-master in the active system to be switched to a PTP-master in the standby system.

The switching unit 313 outputs the announcement information and messages transmitted from the PTP-master in the active system out of the announcement information and messages outputted from the message end sections 311-1 to 311-n, to the active system protocol end section 314 in accordance with the switching control signal. Also, the switching unit 313 outputs the announcement information and messages transmitted from the PTP-master in the standby system out of the announcement information and messages outputted from the message end sections 311-1 to 311-n, to the standby system protocol end section 315 in accordance with the switching control signal.

The active system protocol end section 314 performs synchronous processing by the PTP, for instance, based on a message using the PTP. For instance, as illustrated in FIG. 21, the active system protocol end section 314 obtains time information (T1 to T4) based on the announcement information or message, and calculates a correction amount (or a phase difference amount) for time. The active system protocol end section 314 outputs the calculated correction amount to the phase detection unit 317 and the within system reference timing generation unit 350.

In addition, the active system protocol end section 314 determines a transmission interval of a message (for instance, a Sync follow up message) in the PTP-master based on, for instance, a message using the PTP, and generates a clock signal (CLK) based on the transmission interval. The active system protocol end section 314 outputs the generated clock signal to the PLL functional unit 320.

The standby system protocol end section 315 performs synchronous processing by the PTP based on, for instance, a message using the PTP. The standby system protocol end section 315 calculates a correction amount of time with respect to the PTP-master in the standby system based on a message from the PTP-master in the standby system. The standby system protocol end section 315 monitors, for instance, the amount of correction to the PTP-master in the standby system, and does not monitor any other amount.

The phase margin detection unit 316 determines a frequency of access to the PTP-master in the standby system based on “stepRemoved” transmitted from the PTP-master in the active system.

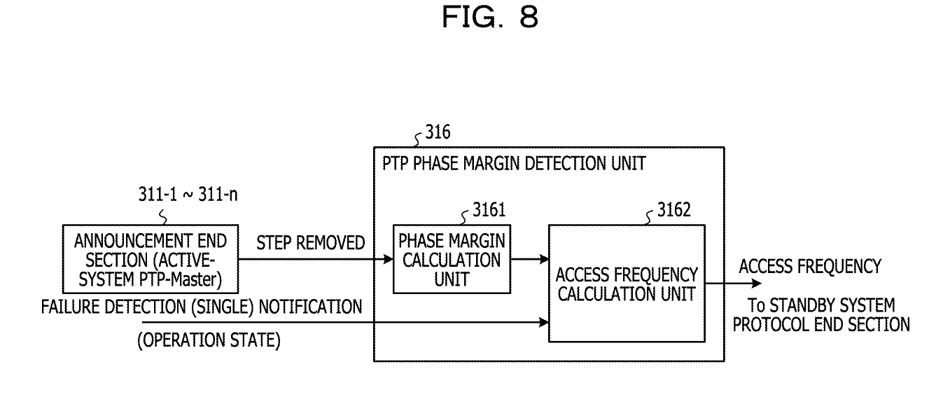

FIG. 8 is a diagram illustrating an example configuration of the phase margin detection unit 316. The phase margin detection unit 316 includes a phase margin calculation unit 3161, and an access frequency calculation unit (hereinafter may be referred to as an “access frequency calculation unit”) 3162 for the PTP-master in the standby system.

The phase margin calculation unit 3161 extracts “stepRemoved” transmitted from the PTP-master in the active system out of the announcement information received from the message end sections 311-1 to 311-n. The phase margin calculation unit 3161 calculates (1 μs−50 ns×n) for the number n of levels included in the “stepRemoved” to determine a phase margin for an acceptable delay amount of ±1 μs defined by the ITU-T.

The access frequency calculation unit 3162 receives the phase margin from the phase margin calculation unit 3161, and calculates a frequency of access to the PTP-master in the standby system. The calculation method will be described later. The access frequency calculation unit 3162 outputs the calculated access frequency to the standby system protocol end section 315. The standby system protocol end section 315 performs synchronous processing by the PTP with the PTP-master in the standby system according to the access frequency. In this case, the standby system protocol end section 315 may notify the PTP-master in the standby system of an access frequency via the message end sections 311-1 to 311-n, for instance. Thus, it is possible for the PTP-master in the standby system to transmit a message using the PTP with the access frequency notified.

It is to be noted that when receiving a failure detection single notification from the phase detection unit 317 in an operation state, the access frequency calculation unit 3162 calculates a second access frequency higher than the calculated first access frequency, and outputs the calculated second access frequency to the standby system protocol end section 315. In the first embodiment, for instance, when a failure of the PTP-master in the active system is detected singly, the BBU 300 detects a failure of the PTP-master in the active system by detecting continuity of variation in the amount of correction to the PTP-master in the standby system with an increased access frequency. However, the BBU 300 may perform synchronous processing by the PTP with the PTP-master in the standby system at the calculated first access frequency without detecting continuity of variation in the amount of correction.

Returning to FIG. 7, the phase detection unit 317 detects a failure of the PTP-master in the active system.

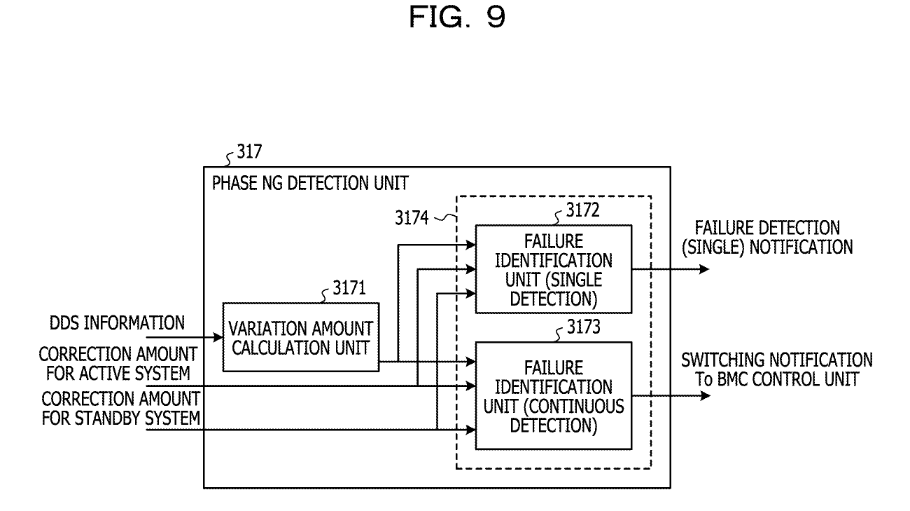

FIG. 9 is a diagram illustrating an example configuration of the phase detection unit 317. The phase detection unit 317 includes a variation amount calculation unit 3171, a failure identification unit (single detection) (hereinafter may be referred to as a “single failure identification unit”) 3172, and a failure identification unit (continuous detection) (hereinafter may be referred to as a “continuous failure identification unit”) 3173.

The variation amount calculation unit 3171 calculates a variation amount (or a variation amount in the DDS value) in the frequency deviation between a clock signal generated by the BBU 300 and a clock signal extracted by the synchronous processing using the PTP, based on the DirectDigital Synthesizer (DDS) information received from the PLL functional unit 320, for instance. Alternatively, the variation amount calculation unit 3171 calculates a variation amount based on the frequency difference between a clock signal used by the PTP-master in the active system and a clock signal used by the BBU 300, based on a message using the PTP, exchanged with the PIP-master in the active system. The details of the DDS information will be described later. The variation amount calculation unit 3171 outputs the calculated variation amount the single failure identification unit 3172 and the continuous failure identification unit 3173.

The single failure identification unit 3172 detects (or identifies) a failure of the PTP-master in the active system based on, for instance, the variation amount and a correction amount for the standby system, received from the standby system protocol end section 315. When detecting a failure even once, the single failure identification unit 3172 outputs a single failure detection notification to the phase margin detection unit 316.

The continuous failure identification unit 3173 also detects (or identifies) a failure of the PTP-master in the active system based on, for instance, the variation amount and a correction amount for the standby system, received from the standby system protocol end section 315. In this case, for instance, when detecting a failure of the PTP-master in the active system continuously, the continuous failure identification unit 3173 outputs a switching notification to the BMC control unit 312.

It is to be noted that in the example of FIG. 9, the single failure identification unit 3172 and the continuous failure identification unit 3173 receive a correction amount for the active system from the active system protocol end section 314, however, may not receive a correction amount for the active system.

Alternatively, the single failure identification unit 3172 and the continuous failure identification unit 3173 may be formed as one component of a failure identification unit 3174. In this case, when identifying a failure even once, the failure identification unit 3174 may output a switching notification.

Return to FIG. 7, the PLL functional unit 320 includes a phase comparator 321, a highly stable oscillator 322, a loop filter 323, a flash memory 324, a DDS unit 325, and a voltage-controlled crystal oscillator (VCXO) 326.

The phase comparator 321 compares the phases between a clock signal received from the PTP functional unit 310 and a clock signal received from the VCXO 326, and outputs a result of the comparison to the loop filter 323.

The highly stable oscillator 322 generates, for instance, a clock signal with a nearly fixed frequency, and outputs the generated clock signal to the loop filter 323 and a DDS processing unit 318. The clock signal may be a clock signal generated by the BBU 300, for instance.

The loop filter 323 performs analogue to digital (AD) conversion on a result of the phase comparison relative to a clock signal from the highly stable oscillator 322, and outputs the comparison result after the A/D conversion to the DDS processing unit 318.

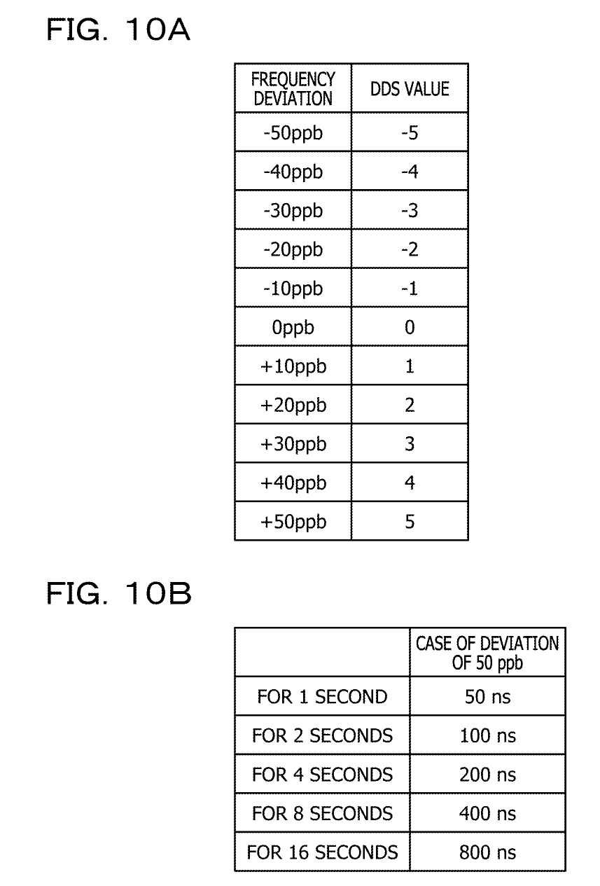

The flash memory 324 stores a DDS value, for instance. The flash memory 324 holds, for instance, a DDS value corresponding to the frequency deviation between a clock signal of the highly stable oscillator 322 and a clock signal extracted by the PTP. For instance, the table illustrated in FIG. 10A may be held. The details of FIG. 10A will be described later.

The DDS unit 325 has, for instance, a waveform memory internally, and reads data from the waveform memory based on a phase corresponding to the phase comparison result from the loop filter 323, and a frequency deviation corresponding to the DDS value read from the flash memory 324. In this process, the DDS unit 325 reads data at the timing of each clock signal outputted from the highly stable oscillator 322. In this manner, for instance, it is possible to match the oscillating frequency (for instance, the frequency of a clock signal outputted from the highly stable oscillator 322) of the BBU 300 to the frequency of a clock signal extracted by the synchronous processing by the PTP. The DDS unit 325 outputs a control voltage corresponding to the read data. It is to be noted that when the BBU 300 is driven by itself, the DDS processing unit 318 operates, for instance, using the DDS value stored in the flash memory 324 without using the output of the phase comparator 321.

The VCXO 326 generates a reference clock signal with a frequency controlled by, for instance, the control voltage outputted from the DDS processing unit 318. The VCXO 326 outputs the generated reference clock signal to the within system reference timing generation unit 350, the within system functional unit 351, the phase comparator 321, and the PTP functional unit 310. It is possible for the PTP functional unit 310 and others to perform processing synchronized with a reference clock signal outputted from the VCXO 326.

The within system reference timing generation unit 350 generates a reference timing signal in the BBU 300 based on a correction amount received from the PTP functional unit 310 and a clock signal received from the PLL functional unit 320. The within system reference timing generation unit 350 has, for instance, a timer internally, the adds a correction amount to time information counted by the timer to correct the time information, and generates a reference timing signal corresponding to the corrected time information. The timer indicates, for instance, the time in the BBU 300.

The within system functional unit 351 performs wireless processing by the TDD system in accordance with a reference clock and a reference timing signal.

It is to be noted that in the BBU 300, the PTP functional unit 310 may be a field programmable gate array (FPGA) 360. For instance, it is possible for the FPGA 360 to implement each function of the PTP functional unit 310 by executing a program stored in the memory.

It is to be noted that the phase comparator 321, the loop filter 323, the DDS unit 325, and the VCXO 326 of the PLL functional unit 320 each may be a digital signal processor (DSP) 330. Furthermore, the within system reference timing generation unit 350 and the within system functional unit 351 each may be a central processing unit (CPU) 362. It is possible for the CPU 362 to execute the function of the within system reference timing generation unit 350 and the within system functional unit 351, for instance, by reading and executing a program stored in the memory.

It is to be noted that the FPGA 360 may be a processor or a controller such as a DSP. Alternatively, the DSP 330 may also be a processor or a controller such as an FPGA. In addition, the CPU 362 may also be a processor or a controller such as a DSP or an FPGA.

<DDS Value>

FIG. 10A illustrates an example DDS value. The DDS value is a value corresponding to the frequency deviation between a clock signal outputted from the highly stable oscillator 322 and a clock signal extracted by synchronous processing by the PTP, for instance. For instance, the DDS unit 325 performs the following processing. Specifically, the DDS unit 325 reads a clock signal extracted by synchronous processing by the PTP from the flash memory 324. In addition, the DDS unit 325 receives a clock signal from the highly stable oscillator 322. The DDS unit 325 then calculates a frequency deviation between two clock signals, and reads a DDS value corresponding to the frequency deviation from a table (for instance, FIG. 10A) stored in the flash memory 324 to obtain the DDS value.

It is to be noted that in FIG. 10A, ppb indicates parts per billion (one billionth=1×10⁻⁹).

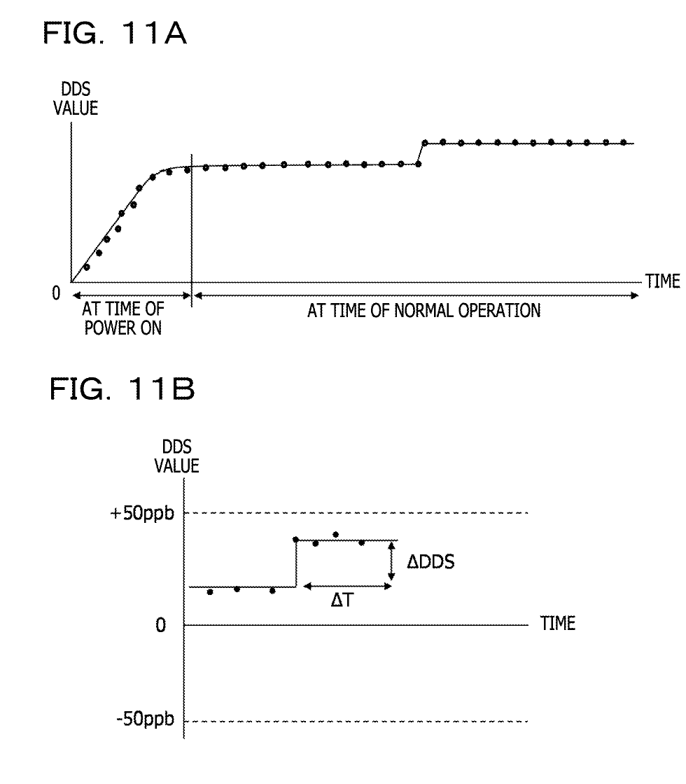

FIG. 11A illustrates an example change in the DDS value. The DDS value changes rapidly at the time of power on, and remains at a nearly fixed value at the time of normal operation. For instance, since the frequency of a clock signal of the highly stable oscillator 322 is different from the frequency of a clock signal extracted by the PTP, at the time of power on, the DDS value changes rapidly so as to follow the frequency deviation. Subsequently, the DDS value has followed the frequency deviation, and remains at a nearly fixed value.

FIG. 11B illustrates an example change in the DDS value when a failure occurs in the switch 200-1 which serves as a PTP-master. The BBU 300-1 serving as a PTP slave performs synchronous processing by the PTP with the switch 200-1 serving as a PTP-master. Thus, when a failure occurs in the switch 200-1 and the oscillating frequency in the switch 200-1 changes, the frequency of a clock signal of the BBU 300-1 is caused to change so as to follow the oscillating frequency in the BBU 300-1. The change in the oscillating frequency in the switch 200-1, caused by a failure of the switch 200-1 appears as a change in the DDS value in the BBU 300-1. Therefore, a change in the DDS value allows a failure of the switch 200-1 serving as a PTP-master to be detected. However, in the first embodiment, a failure of the PTP-master is detected in the BBU 300-1 in consideration of the correction amount of time to the PTP-master in the standby system. The details will be described in an operation example.

It is to be noted that although a variation amount in the frequency deviation between two clock signals is monitored in the BBU 300-1, the variation amount is calculated, for instance, by ΔDDS/ΔT where ΔDDS is the variation amount and ΔT is the variation time. Such monitoring and calculation of a variation amount are performed, for instance, by the two failure identification units 3172, 3173 of the phase detection unit 317.

Also, there is not necessarily a DDS value corresponding to any frequency deviation without limitation, and there is a certain limitation. For instance, when the frequency accuracy exceeds ±50 ppb, a limiter of the highly stable oscillator 322 starts to work. The frequency accuracy corresponds to, for instance, the definition of RRH and the radio frequency used between terminals.

<Operation Example>

Next, an operation example will be described. First, an example of change in the time and the frequency at the occurrence of a failure in the PTP-master in the active system or the PTP-master in the standby system will be described, then an operation example at the occurrence of a failure will be described. In either case, description is given under the assumption that the BBU 300-1 serves as a PTP slave, the switch 200-1 serves as a PTP-master in the active system, and the switch 200-N serves as a PTP-master in the standby system.

Here, the correction amount indicates an amount based on the phase difference of time between the BBU 300-1 and the switch 200-1 (or the switch 200-N), for instance. Also, the variation amount indicates an amount based on the difference between the frequency (or the oscillating frequency) of the clock signal of the BBU 300-1 and the frequency (or the oscillating frequency) of the clock signal of the switch 200-1 (or the switch 200-N), for instance. The variation amount is, for instance, a variation amount in the DDS value.

<Example of Change in Time and Frequency at Occurrence of Failure>

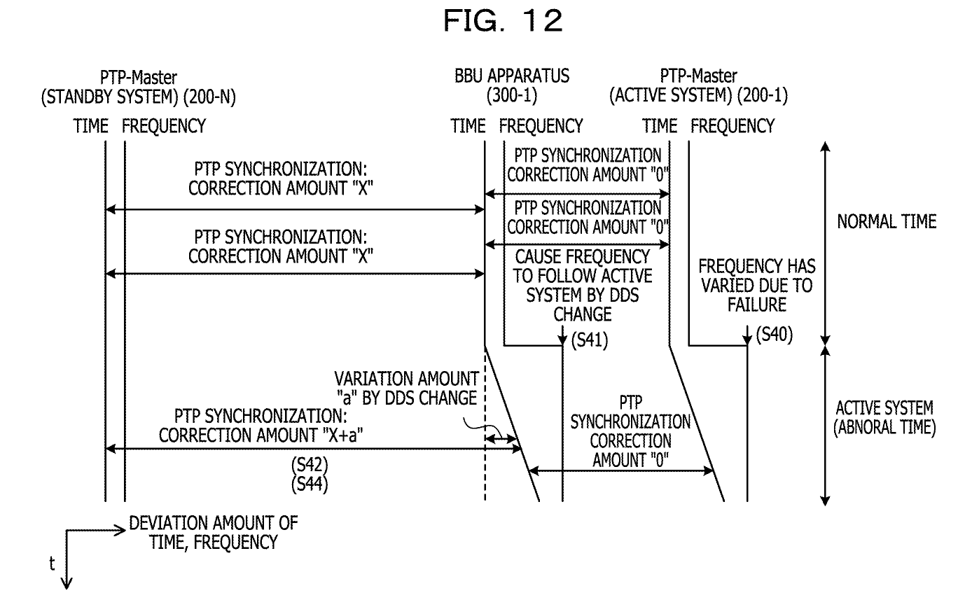

FIGS. 12 to 15 each illustrate an example of change in the time and the frequency at the occurrence of a failure in the PTP-master in the active system or the PTP-master in the standby system.

<1. Case Where Failure Occurs in PTP Master in Active System>

FIG. 12 illustrates an example of change in the time and the frequency at the occurrence of a failure in the PTP-master in the active system. Since the BBU 300-1 performs synchronous processing by the PTP with the switch 200-1 serving as the PTP-master in the active system, the BBU 300-1 is synchronized with the time of the switch 200-1. In the example of FIG. 12, the correction amount is “0”. On the other hand, the BBU 300-1 performs PTP synchronization with the switch 200-N which serves as a PTP-master in the standby system, and in this case, the correction amount is “X”. It is possible for the BBU 300-1 to synchronize with the time of the switch 200-N by adding the correction amount “X” to the time of the self-station.

When a failure occurs in the switch 200-1 serving as the PTP-master in the active system then the oscillating frequency of the switch 200-1 changes (S40), as described above, due to the synchronous processing by the PTP, the oscillating frequency of the BBU 300-1 also follows the oscillating frequency of the switch 200-1 and changes (S41). Therefore, the DDS value also varies.

However, in this case, the BBU 300-1 is synchronized with the switch 200-1 in time by synchronous processing. Therefore, even when the time of the switch 200-1 deviates as compared with the pre-failure time, the BBU 300-1 performs synchronous processing to synchronize with the time. Therefore, the correction amount of time maintains to be “0” (S43).

In contrast, the BBU 300-1 serves as a PTP-master in the standby system for the switch 200-N, and thus does not correct the time. Since the BBU 300-1 corrects the time to the switch 200-1 serving as the PTP-master in the active system, the time of the BBU 300-1 relative to the switch 200-N serving as the PTP-master in the standby system gradually deviates. Therefore, the correction amount of the time to the switch 200-N is “X+a” (S42). The variation amount “a” in the correction amount may be, for instance, an amount corresponding to the variation amount in the DDS value. In this case, the BBU 300-1 determines that the switch 200-N in the standby system is normal because a variation amount in the active system is only considered in the correction amount “X+a” (S44).

In other words, the BBU 300-1 monitors a variation amount in the frequency and a time correction amount in the standby system, and when the variation amount and the correction amount change, it is possible to detect that the switch 200-1 serving as the PTP-master in the active system has failed.

<2. Case Where Failure Occurs in PTP Master in Standby System>

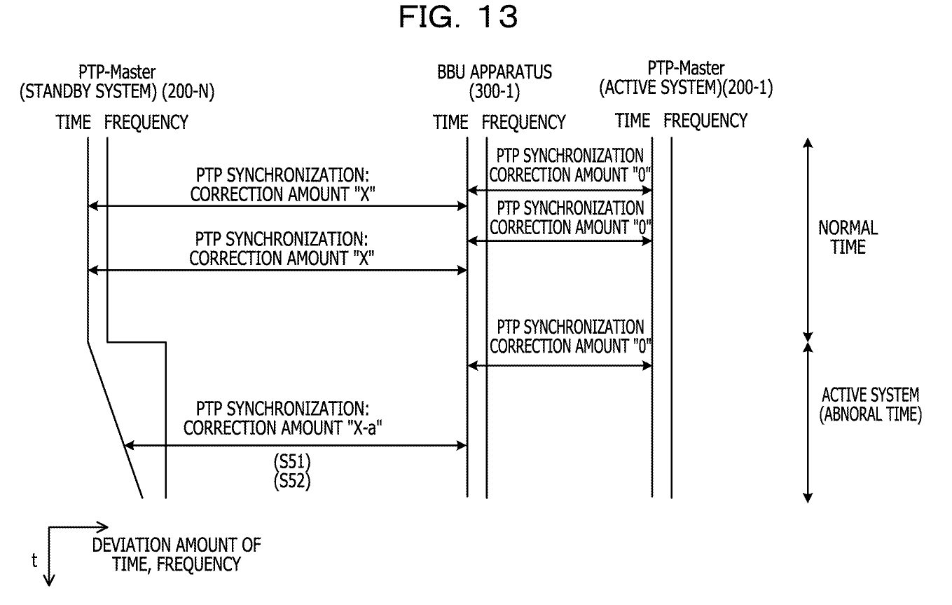

FIG. 13 illustrates an example of change in the time and the frequency at the occurrence of a failure in the PTP-master in the standby system.

Since the BBU 300-1 performs frequency synchronization and time synchronization with the switch 200-1 serving as the PTP-master in the active system, even when the switch 200-N serving as the PTP-master in the standby system fails, the correction amount of time maintained at “0” and the frequency is not varied.

However, in the switch 200-N serving as the PTP-master in the standby system, the oscillating frequency changes (S50) and the time also deviates accordingly. Therefore, in the BBU 300-1, the correction amount of time to the switch 200-N changes along with deviation of the time of the switch 200-N (S51). In the example of FIG. 13, the correction amount of time to the switch 200-N is “X-a” at a certain time point. In this case, a variation value relative to the switch 200-1 in the active system does not occur, and only a correction amount to the switch 200-N in the standby system has changed, and thus it is possible for the BBU 300-1 to determine a failure of the switch 200-N in the standby system (S52).

In other words, when change in the variation amount is not detected and the amount of correction to a PTP-master in the standby system changes, it is possible for the BBU 300-1 to detect that the switch 200-N serving as the PTP-master in the standby system has failed.

<3. Case Where Variation Amount in Frequency is Within Allowable Value (Failure of BBU)>

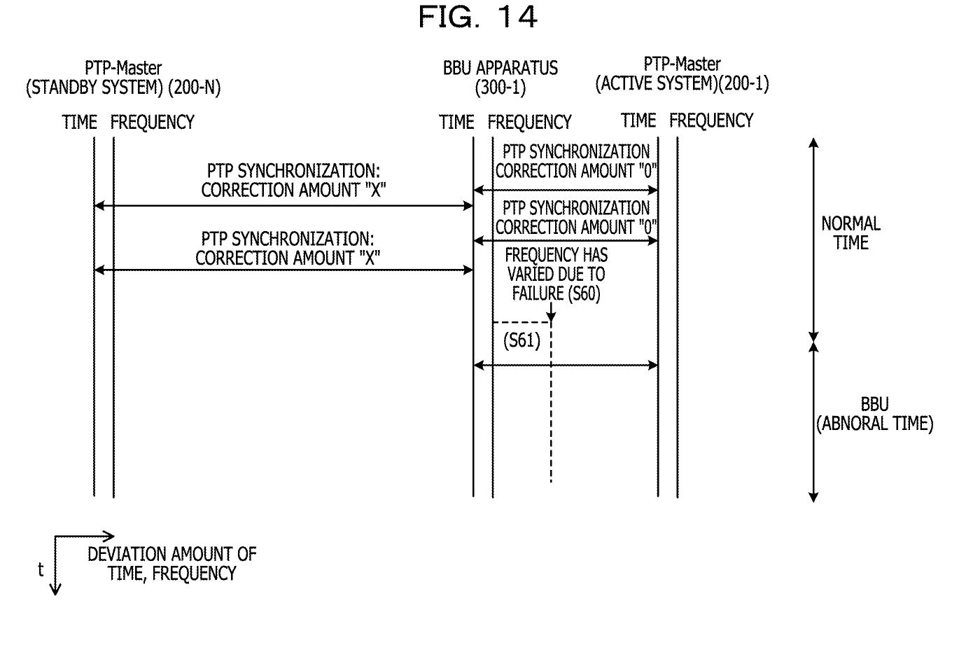

FIG. 14 illustrates an example of change in the time and the frequency when the BBU 300-1 has failed.

In the BBU 300-1, due to a failure of the self-station, for instance, the frequency of a clock signal outputted from the highly stable oscillator 322 changes (S60). Due to this change, the frequency deviation between the frequency of a clock signal extracted by synchronous processing by the PTP, and the frequency of a clock signal outputted from the highly stable oscillator 322 also changes. Therefore, the variation amount also changes.

However, when the variation amount is within a range of acceptable values, it is possible for the BBU 300-1 to match its frequency to the frequency (the frequency of the switch 200-1 serving as the PTP-master in the active system) of a clock signal extracted by the PTP, using the DDS value corresponding to the variation amount (S61). The acceptable value may be, for instance, ±50 ppb which is a limiting value of the frequency accuracy of the highly stable oscillator 322.

In other words, the BBU 300-1 monitors the correction amount and the variation amount, and when the correction amount does not change and the variation amount changes, it is possible to detect a failure of the self-station. In this case, when the variation amount is within a range of acceptable values, it is possible to continue the synchronous processing by the PTP with the PTP-master in the active system by changing the DDS value.

It is to be noted that in the case of <1. Case Where Failure Occurs in PTP Master in Active System> described above, for instance, the variation amount is within a range of acceptable values. The following is the case where the acceptable values are exceeded.

<4. Case Where Variation Amount in Frequency Exceeds Allowable Value (Failure of BBU)>

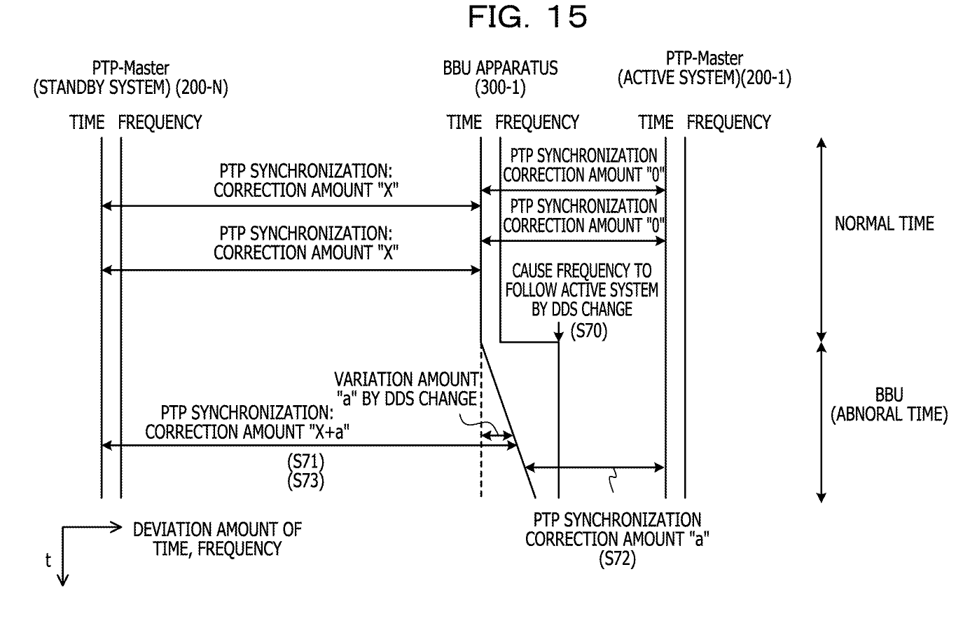

FIG. 15 illustrates an example of change in the time and the frequency when the BBU 300-1 has failed.

Due to a failure of the BBU 300-1, the oscillating frequency of the BBU 300-1 varies, and the DDS value also varies to absorb the variation. The example of FIG. 15 indicates the case where the variation amount in the frequency exceeds an acceptable value and changes.

The BBU 300-1 performs time synchronization to synchronize with the time of the switch 200-1 which serves as a PTP-master in the active system. However, due to a failure of the BBU 300-1 itself, the time also deviates as compared with the pre-failure time. The correction amount made by time synchronization with the switch 200-1 has been “0”, but gradually changes and becomes “a” at a certain time point (S70, S72).

In the BBU 300-1, relative to the switch 200-N serving as the PTP-master in the standby system, the time deviates for a deviation of time for the correction amount “a”. In the BBU 300-1, the amount correction to the switch 200-N is “X+a” at a certain time point (S71). In this case, the BBU 300-1 may determine that the switch 200-N in the standby system is normal because the variation amount “a” of the switch 200-1 in the active system is only considered in the correction amount “X+a” of the switch 200-N in the standby system (S73).

In other words, the BBU 300-1 monitors the amount of correction to the PTP-master in the standby system and the variation amount in the DDS value, and when the variation amount exceeds an acceptable value and the correction amount changes, it is possible to detect a failure of the self-station.

<Frequency of Access to PTP Master in Standby System>

As described above, in the first embodiment, the BBU 300-1 sets the frequency of access to the PTP-master in the standby system to be lower than the frequency of access to the PTP-master in the active system.

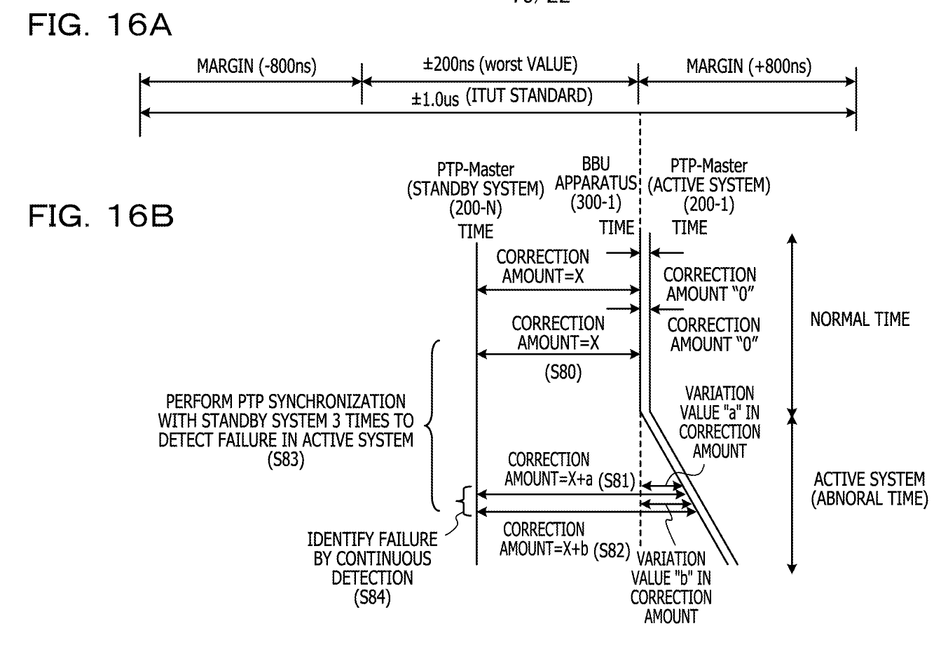

FIG. 16A illustrates an example phase margin. FIG. 16A also illustrates an example in which the number of levels is four in a path from the grand-master 100 to the switch 200-1 serving as the PTP-master in the active system, and the phase margin is ±800 ns. In this case, there is no problem even when deviation of 800 ns occurs in the BBU 300-1 relative to the time of the grand-master 100.

In contrast, the DDS value has a limiting value of ±50 ppb, and when the limiting value is exceeded, a limiter starts to work. As the worst case, the case in which the frequency of a clock signal of the highly stable oscillator 322 of the BBU 300-1 deviates by ±50 pbb is considered.

FIG. 10B illustrates an example phase difference when the frequency deviates by 50 ppb. When a frequency deviation by ±50 ppb continues for one second, a deviation of 50 ppb×1 sec=50 ns (=5×10⁻⁹ seconds) occurs, and when the frequency deviation continues for two seconds, a deviation of 100 ns occurs. When the frequency deviation continues for 16 seconds, a deviation of 800 ns occurs which is the same as the phase margin of the BBU 300-1. That is, in the worst case, after 16 seconds, the phase of a clock signal of the BBU 300-1 deviates by 800 ns, and reaches the acceptable range (±1 μs) of the standard.

FIG. 16B illustrates an example of change in the time in the BBU 300-1 and the switches 200-1, 200-N. After accessing to the switch 200-N serving as the PTP-master in the standby system, the BBU 300-1 only has to access to the switch 200-N one time for at least 16 seconds to monitor the correction amount. Thus, for instance, it is possible for the BBU 300-1 to correct the deviation of the oscillating frequency of the BBU 300-1 by performing frequency synchronization with the PTP-master in the active system without causing a phase deviation by 800 ns which is a phase margin.

It is to be noted that in the example of FIG. 16B, after accessing (S80) to the switch 200-N, the BBU 300-1 accesses to the switch 200-N twice for 16 seconds (S81, S82). Here, an example is presented in which a failure of the switch 200-1 serving as the PTP-master in the active system is detected continuously.

For instance, when the BBU 300-1 transmits messages from a Sync message to a Delay Response message once after exchanging an announcement message with the switch 200-1, a message may be repeatedly exchanged for 128 times within one second. However, after accessing to the switch 200-N, the BBU 300-1 only has to access to the switch 200-N at least once within 16 seconds, and thus it is possible to set the frequency of access to the PTP-master in the standby system to be lower than the frequency of access to the PTP-master in the active system. Thus, it is possible for the BBU 300-1 to reduce the load to the PTP network.

<Entire Operation Example>

Next, the entire operation example will be described. Since the following includes what has been already described, concise description is given as appropriate.

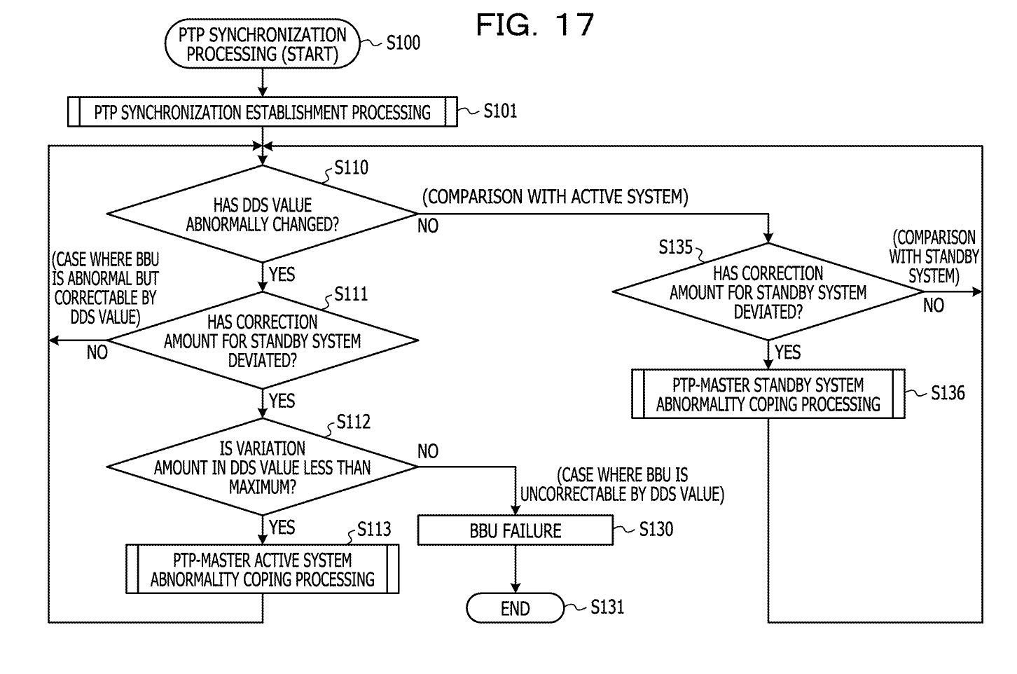

FIG. 17 is a flowchart illustrating the entire operation example. Each processing illustrated in FIG. 17 is performed by the BBU 300-1, for instance.

After starting PTP synchronous processing (S100), the BBU 300-1 performs PTP synchronization establishment processing (S101).

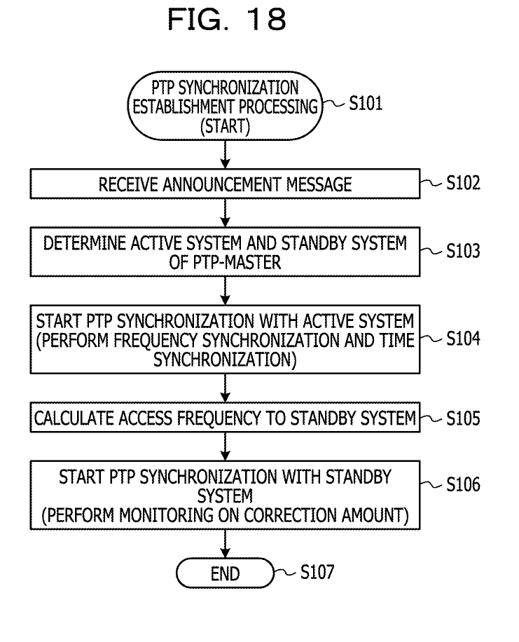

FIG. 18 is a flowchart illustrating an operation example of the PTP synchronization establishment processing. After starting the PTP synchronization establishment processing (S101), the BBU 300-1 receives an announcement message transmitted from each of the switches 200-1 to 200-N (S102). For instance, each of the message end sections 311-1 to 311-N receive an announcement message transmitted from corresponding one of the switches 200-1 to 200-N.

Subsequently, the BBU 300-1 determines the active system and the standby system of the PTP-master(S103). For instance, the BMC control unit 312 may set the switch having the best performance to be the PTP-master in the active system and the switch having the second best performance to be the PTP-master in the standby system by utilizing the BMC algorithm. For instance, the BMC control unit 312 determines that the switch 200-1 is the PTP-master in the active system and the switch 200-N is the PTP-master in the standby system by using the BMC algorithm based on the information included in the announcement message.

Subsequently, the BBU 300-1 starts PTP synchronization with the PTP-master in the active system (S104). In this case, the BBU 300-1 performs time synchronization (for instance, FIG. 21) and frequency synchronization (for instance, FIG. 3) by the synchronous processing by the PTP with the switch 200-1. For instance, the active system protocol end section 314 performs synchronous processing based on a message by the PTP.

Subsequently, the BBU 300-1 calculates an access frequency to the standby system (S105). For instance, the access frequency calculation unit 3162 calculates an access frequency based on the information on the number of levels included in the announcement message.

Subsequently, the BBU 300-1 starts PTP synchronization with the PTP-master in the standby system at the calculated access frequency (S106). In this case, the BBU 300-1 monitors the correction amount of time and does not monitor the variation amount in the frequency by synchronous processing by the PTP with the switch 200-N. For instance, the standby system protocol end section 315 accesses to the switch 200-N to perform synchronous processing by the PTP at the access frequency calculated by the phase margin detection unit 316.

The PTP synchronization establishment processing is completed (S107).

Returning to FIG. 17, subsequently, the BBU 300-1 detects whether or not the DDS value has abnormally changed (S110). For instance, the single failure identification unit 3172 or the continuous failure identification unit 3173 (hereinafter may be referred to as the “failure identification unit 3174”) receives a DDS value from the flash memory 324, and performs the present processing according to whether or not the received DDS value has varied. As described above, the DDS value is a value (for instance, FIG. 10A) corresponding to the difference between the oscillating frequency of the switch 200-1 and the oscillating frequency of the BBU 300-1, for instance.

When the DDS value has varied (Yes in S110), the BBU 300-1 determines whether or not the correction amount of time to the switch 200-N serving as the PTP-master in the standby system has deviated (S111). For instance, the failure identification unit 3174 determines whether or not the correction amount received from the standby system protocol end section 315 has varied.

When the correction amount of time to the PTP-master in the standby system has deviated (Yes in S111), the BBU 300-1 determines whether or not the variation amount in the DDS value is less than a maximum (S112). For instance, the failure identification unit 3174 determines whether or not the variation amount in the DDS value exceeds an acceptable value.

When the variation amount in the DDS value is less than a maximum (Yes in S112), the BBU 300-1 performs active system PTP-master abnormality coping processing (hereinafter may be referred to as “abnormality coping processing”) (S113).

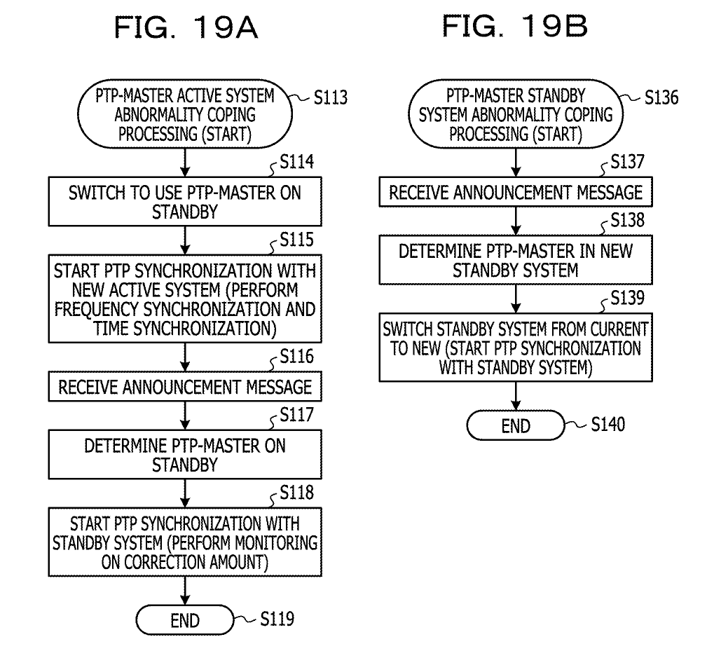

FIG. 19A is a flowchart illustrating an example of abnormality coping processing. When the BBU 300-1 starts the abnormality coping processing (S113), the BBU 300-1 changes the PTP-master from the active system to the standby system (S114).

When the DDS value has varied and the variation amount is an acceptable value or low (Yes in S110, Yes in S112), and the correction amount to the switch 200-N has changed (Yes in S111), the current situation corresponds to the example of FIG. 12. In this case, the BBU 300-1 determines that the switch 200-1 serving as the PTP-master in the active system has failed, and switches from the switch 200-1 to the switch 200-N. For instance, the failure identification unit 3174 outputs a switching notification to the BMC control unit 312, the BMC control unit 312 controls the switching unit 313 to redirect the output from the switch 200-N to the active system protocol end section 314.

Returning to FIG. 19A, subsequently, the BBU 300-1 starts PTP synchronization with a new active system PTP-master (S115). The BBU 300-1 then receives an announcement message from each switch other than the switches 200-1, 200-N (S118), and determines a switch serving as the PTP-master in the standby system utilizing the BMC algorithm (S119). The BBU 300-1 starts the PTP synchronization with the determined switch (S118), and completes the abnormality coping processing (S119).

Returning to FIG. 17, when the BBU 300-1 completes the abnormality coping processing (S113), the flow proceeds to S110, and the BBU 300-1 repeats the above-described processing on the PTP-master in the active system and the PTP-master in the standby system after switching.

On the other hand, when the variation amount in the DDS value is greater than or equal to a maximum (No in S112), the BBU 300-1 determines that the self-station has failed (S130), and completes the processing (S131). This corresponds to the case of FIG. 15.

When the amount of correction to the PTP-master in the standby system has not deviated (No in S111), the flow proceeds to S110, and the BBU 300-1 repeats the above-described processing. This corresponds to the case of FIG. 14. The BBU 300-1 may cope with a failure of the self-station by changing the DDS value, and thus does not switch from the active system to the standby system.

When detecting no variation amount in the DDS value (No in S110), the BBU 300-1 determines whether or not the amount of correction to the PTP-master in the standby system has deviated (S135).

When the amount of correction to the PTP-master in the standby system has deviated (Yes in S135), the BBU 300-1 performs the standby system PTP-master abnormality coping processing (S136). This case corresponds to FIG. 13, and since the amount of correction to the PTP-master in the standby system has deviated and the variation amount has not varied. Thus, the BBU 300-1 determines a failure of the PTP master in the standby system, and performs the standby system PTP-master abnormality coping processing.

FIG. 19B is a flowchart illustrating an example of the standby system PTP-master abnormality coping processing. When starting the processing (S136), the BBU 300-1 receives an announcement message from each switch other than the switches 200-1, 200-N (S137), and determines a switch that serves as the PTP master in a new standby system (S138). For instance, the BMC control unit 312 determines a new switch based on an announcement message from the message end sections 311-2 to 311-n other than the message end sections 311-1, 311-N respectively corresponding to the switches 200-1, 200-N.

The BBU 300-1 then switches the switch 200-N serving as the PTP master in the standby system to a newly selected switch (S139), and completes the standby system PTP-master abnormality coping processing (S140).

Returning to FIG. 17, when completing the standby system PTP-master abnormality coping processing (S136), the flow proceeds to S110, and the BBU 300-1 repeats the above-described processing on the newly selected standby system PTP master and the PTP master in the active system.

When the amount of correction to the PTP-master in the standby system has not deviated (No in S135), the flow proceeds to S110, and the BBU 300-1 repeats the above-described processing. In this case, the DDS value does not vary and the amount of correction to the PTP-master in the standby system has not varied, and thus the BBU 300-1 repeats the above-described processing without switching the PTP master.

### Other Embodiments

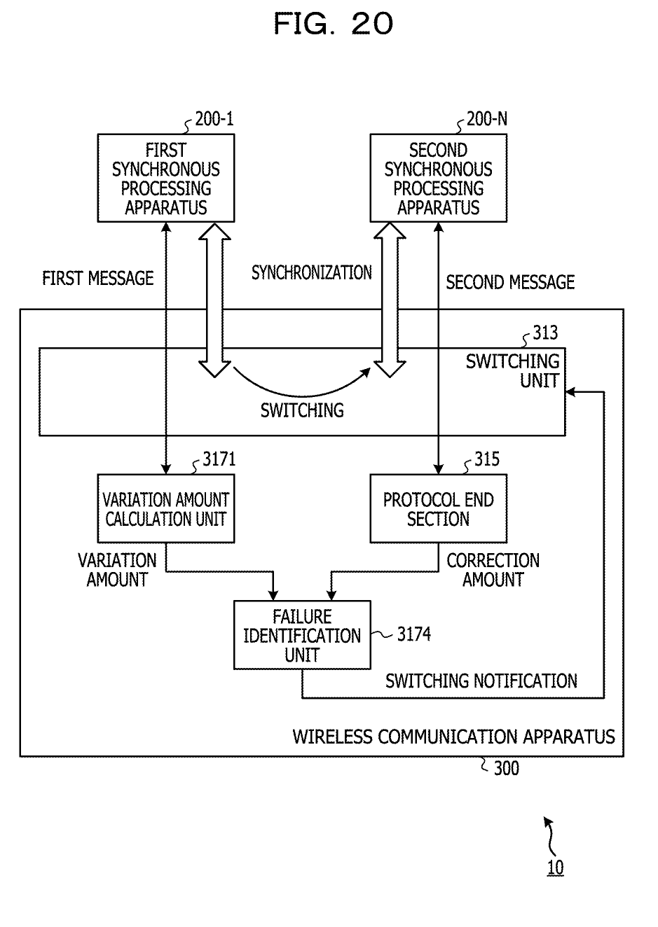

FIG. 20 illustrates an example configuration of the communication system 10. The communication system 10 includes a first synchronous processing apparatus 200-1, a second synchronous processing apparatus 200-N, and a wireless communication apparatus 300.

The first synchronous processing apparatus 200-1 corresponds, for instance, to the switch 200-1 in the active system in the first embodiment. Also, the second synchronous processing apparatus 200-N corresponds, for instance, to the switch 200-N in the standby system in the first embodiment. It is assumed that the wireless communication apparatus 300 performs synchronous processing by the PTP with the first synchronous processing apparatus 200-1, and performs time synchronization and frequency synchronization.

The wireless communication apparatus 300 includes a switching unit 313, a protocol end section 315, a variation amount calculation unit 3171, and a failure identification unit 3174. The switching unit 313, the protocol end section 315, the variation amount calculation unit 3171, and the failure identification unit 3174 correspond to, for instance, the switching unit 313, the standby system protocol end section 315, the variation amount calculation unit 3171, and the failure identification unit 3174 in the first embodiment.

The variation amount calculation unit 3171 calculates a variation amount based on the frequency difference between a first reference signal used by the first synchronous processing apparatus 200-1 and a second reference signal used by the wireless communication apparatus 300, based on a first message exchanged with the first synchronous processing apparatus 200-1.

The protocol end section 315 calculates a correction amount based on the phase difference between the time in the second synchronous processing apparatus 200-N and the time in the wireless communication apparatus based on a second message exchanged with the second synchronous processing apparatus 200-N.

When detecting a failure in the first synchronous processing apparatus 200-1 based on the variation amount and the correction amount, the failure identification unit 3174 outputs a switching notification.

The switching unit 313 switches an object for synchronization from the first synchronous processing apparatus 200-1 to the second synchronous processing apparatus 200-N in accordance with the switching notification.

In this manner, in the communication system 10, it is possible for the wireless communication apparatus 300 to detect a failure of the first synchronous processing apparatus 200-1 based on a variation amount according to the frequency difference between the reference signals and a correction amount according to the phase difference between the times. Therefore, it is possible for the wireless communication apparatus 300 to detect a failure of the first synchronous processing apparatus 200-1 serving as the PTP master in the active system without waiting for receiving an announcement message indicating an occurrence of a failure from the first synchronous processing apparatus 200-1. Thus, it is possible for the wireless communication apparatus 300 to quickly switch between PTP masters without making transition to the self-driven mode compared with the case where receiving of an announcement message is waited, and thus TDD service for terminal apparatuses may be continued. Consequently, the communication system 10 is able to protect against degradation of service.

In the example described above, description has been given by using the PTP as the time synchronization protocol. For instance, a Simple Network Time Protocol (SNTP), a Network Time Protocol (NTP) and others may be used. Similarly to the PTP, with these time synchronization protocols, time synchronization and frequency synchronization are possible by exchanging a packet or a message. Therefore, similarly to the above-described embodiments, the BBU 300 may be implemented by utilizing such a packet and a message.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A wireless communication apparatus comprising:
a memory; and
a processor coupled to the memory and configured to:
calculate a variation amount based on a frequency difference between a first clock signal in a first synchronous processing apparatus and a second clock signal in the wireless communication apparatus according to a first message exchanged between the first synchronous processing apparatus and the wireless communication apparatus;
calculate a correction amount based on a phase difference between a first time in a second synchronous processing apparatus and a second time in the wireless communication apparatus according to a second message exchanged between the second synchronous processing apparatus and the wireless communication apparatus; and
when a failure is detected in the first synchronous processing apparatus based on the variation amount and the correction amount, switch an object for synchronization from the first synchronous processing apparatus to the second synchronous processing apparatus.

2. The wireless communication apparatus according to claim 1,
wherein the processor detects an occurrence of a failure in the first synchronous processing apparatus based on a variation in the variation amount and the correction amount.

3. The wireless communication apparatus according to claim 1,
wherein when the correction amount varies and the variation amount does not vary, the processor detects an occurrence of a failure in the second synchronous processing apparatus.

4. The wireless communication apparatus according to claim 1,
wherein when the variation amount varies within an acceptable value and the correction amount does not vary, the processor detects an occurrence of a failure in the wireless communication apparatus.

5. The wireless communication apparatus according to claim 1,
wherein when the variation amount varies and exceeds an acceptable value and the correction amount varies, the processor detects an occurrence of a failure in the wireless communication apparatus.

6. The wireless communication apparatus according to claim 1,
wherein a frequency of exchange of the first message between the first synchronous processing apparatus and the wireless communication apparatus is higher than a first frequency of exchange of the second message between the second synchronous processing apparatus and the wireless communication apparatus.

7. The wireless communication apparatus according to claim 6,
wherein the processor further extracts, from the first message, a number of synchronous processing apparatuses including the first synchronous processing apparatus, that perform synchronous processing based on time information obtained by a grand-master apparatus using a GPS, and the processor calculates the first frequency based on a phase difference acceptable value for the number and the time information, the synchronous processing apparatuses intervening between the grand-master apparatus and the wireless communication apparatus reached via the first synchronous processing apparatus, and
a protocol end section exchanges the second message with the second synchronous processing apparatus according to the first frequency.

8. The wireless communication apparatus according to claim 6,
wherein when the variation amount and the correction amount vary, the processor exchanges the second message with the second synchronous processing apparatus at a second frequency higher than the first frequency.

9. The wireless communication apparatus according to claim 1,
wherein the first and second messages are messages defined by Precision Time Protocol (PTP), and
the processor calculates the variation amount and the correction amount each in accordance with synchronous processing defined by the PTP.

10. A time synchronization method for a wireless communication apparatus comprising:
calculating, by a processor, a variation amount based on a frequency difference between a first clock signal in a first synchronous processing apparatus and a second clock signal in the wireless communication apparatus according to a first message exchanged between the first synchronous processing apparatus and the wireless communication apparatus;
calculating, by a processor, a correction amount based on a phase difference between a first time in a second synchronous processing apparatus and a second time in the wireless communication apparatus according to a second message exchanged between the second synchronous processing apparatus and the wireless communication apparatus; and
when a failure is detected in the first synchronous processing apparatus based on the variation amount and the correction amount, switching, by a processor, an object for synchronization from the first synchronous processing apparatus to the second synchronous processing apparatus.

11. A communication system comprising:
a first synchronous processing apparatus;
a second synchronous processing apparatus; and
a wireless communication apparatus communicating with the first and second synchronous apparatuses and configured to:
calculate a variation amount based on a frequency difference between a first clock signal in the first synchronous processing apparatus and a second clock signal in the wireless communication apparatus according to a first message exchanged between the first synchronous processing apparatus and the wireless communication apparatus;
calculate a correction amount based on a phase difference between a first time in the second synchronous processing apparatus and a second time in the wireless communication apparatus according to a second message exchanged between the second synchronous processing apparatus and the wireless communication apparatus; and
when a failure is detected in the first synchronous processing apparatus based on the variation amount and the correction amount, switch an object for synchronization from the first synchronous processing apparatus to the second synchronous processing apparatus.
